(19) United States
(12) Patent Application Publication
(10) Pub. No.: US 2006/0130766 A1
(43) Pub. Date: Jun. 22, 2006

(54) Deposition source and deposition apparatus including deposition source

(76) Inventors: Do-Geun Kim, Suwon-si (KR); Jae-Hong Ahn, Suwon-si (KR); Kwan-Seop Song, Suwon-si (KR); Myung-Soo Huh, Suwon-si (KR); Seok-Heon Jeong, Suwon-si (KR)

Correspondence Address: Robert E. Bushnell, Suite 300, 1522 K Street, N.W., Washington, DC, 20005, US

(21) Appl. No.: 11/289,631

(22) Filed: Nov. 30, 2005

(30) Foreign Application Priority Data
Dec. 1, 2004 (KR) 10-2004-0099825

(51) Int. Cl. C23C 16/00

(52) U.S. Cl. 118/726

(57) ABSTRACT

A deposition source having a constant deposition rate and high reproducibility, and a deposition apparatus including the deposition source includes: a heating chamber having a linear opening portion; and a cover including a plurality of holes and attached to the linear opening portion of the heating chamber. The distances between the holes formed on the cover vary along a long side direction of the linear opening portion of the heating chamber. The number of holes formed on the cover along a long side direction of the linear opening portion of the heating chamber can also vary.

### CLAIM OF PRIORITY

This application makes reference to, incorporates the same herein, and claims all benefits accruing under 35 U.S.C.§119 from an application earlier filed in the Korean Intellectual Property Office on Dec. 1, 2004 and there duly assigned Serial No. 10-2004-0099825.

### BACKGROUND OF THE INVENTION

1. Field of the Invention

The present invention relates to a deposition source and a deposition apparatus including the deposition source, and more particularly, to a deposition source having a constant deposition rate and a high reproducibility.

2. Description of the Related Art

ElectroLuminescence (EL) display apparatus are self-emissive display apparatus, and have advantages such as a wide viewing angle, high contrast, and fast response speed, and thus, are considered to be next generation display apparatus.

EL display apparatus can be divided into inorganic EL display apparatus and organic EL display apparatus according to the material forming an EMission Layer (EML) thereof. The organic EL display apparatus have superior properties to those of the inorganic EL display apparatus in terms of brightness, driving voltage, and response speed, and can display multi-colors.

An organic EL device used in the organic EL display apparatus includes an intermediate layer having at least an EML between electrodes facing each other. The intermediate layer can include various layers, for example, a hole injection layer, a hole transport layer, an EML, an electron transport layer, and an electron injection layer. In the organic EL device, the intermediate layers are organic thin films formed of an organic material.

During fabrication of the organic EL device, the organic thin films such as the hole injection layer, the hole transport layer, the EML, the electron transport layer, and the electron injection layer, or electrodes formed on a substrate are formed by depositing using a deposition apparatus.

According to the deposition method, a substrate is mounted in a vacuum chamber, and a chamber containing a material to be deposited is heated to evaporate the material in the chamber and fabricate the thin film.

The organic material forming the thin films of the organic EL device is evaporated or sublimated under a 10⁻⁶−10⁻⁷ torr environment and a temperature range of about 250° C.-450° C. The material forming the electrodes is evaporated at a higher temperature than that of the organic material, and the evaporation temperature can be varied according to the kinds of material. Mg is evaporated at a temperature of about 500° C.-600° C., and Ag is evaporated at a temperature of 1000° C. or higher. In addition, Al used to form the electrodes is evaporated at a temperature of about 1000° C., and Li is evaporated at a temperature of 300° C.

The most important thing in depositing the organic material or the electrode material onto the substrate is to make a thickness of the film deposited on the entire substrate uniform. Therefore, various efforts for optimizing the evenness of the thin film deposited on the substrate have been performed.

A linear deposition source includes a plurality of holes formed on a front surface thereof. The material in the deposition source is evaporated and discharged through the holes. The holes formed on the deposition source are spaced apart from each other at equivalent distances, and thus, the thickness of the thin film deposited by the deposition source is not uniform. In particular, the thickness of the deposited thin film becomes thinner in a direction toward the edges of the thin film.

In order to solve the above problem, the substrate is rotated or a distance between the deposition source and the substrate is maximized. However, there is a limitation as to increasing the distance between the substrate and the deposition source due to the limitation of size. In addition, when the substrate is rotated, the density (thickness) of the thin film deposited on the substrate is not uniform according to an incident angle of the deposited material onto the substrate.

### SUMMARY OF THE INVENTION

The present invention provides a deposition source having a constant deposition rate and a high reproducibility, and a deposition apparatus including the deposition source.

According to one aspect of the present invention, a deposition source is provided including: a heating chamber having a linear opening portion; and a cover including a plurality of holes and attached to the linear opening portion of the heating chamber. The distances between the holes vary along a long side direction of the linear opening portion of the heating chamber.

The distances between the holes are preferably reduced in a direction towards either end portion from a center of the linear opening portion in the long side direction of the linear opening portion of the heating chamber.

The holes on the cover are preferably arranged in a row in the long side direction of the linear opening portion of the heating chamber.

A maximum diameter of the holes on the cover is preferably less than a width of the linear opening portion of the heating chamber.

The cover is preferably integral with the heating chamber.

According to another aspect of the present invention, a deposition source is provided including: a heating chamber having a linear opening portion; and a cover including a plurality of holes and attached to the linear opening portion of the heating chamber. The number of holes arranged in a short side direction of the linear opening portion of the heating chamber varies along a long side direction of the linear opening portion of the heating chamber.

The number of holes arranged in the short side direction of the linear opening portion of the heating chamber preferably increases in a direction towards either end portion from a center of the linear opening portion in the long side direction of the linear opening portion of the heating chamber.

Distances between the plurality of holes are preferably constant in the long side direction of the linear opening portion of the heating chamber.

Distances between the plurality of holes on the cover are preferably reduced in a direction towards either end portion from a center of the linear opening portion in the long side direction of the linear opening portion of the heating chamber.

A maximum diameter of the plurality of holes is preferably less than a width of the linear opening portion of the heating chamber.

The cover is preferably integral with the heating chamber.

According to still another aspect of the present invention, a deposition apparatus having a deposition source is provided including: a heating chamber having a linear opening portion; and a cover including a plurality of holes and attached to the linear opening portion of the heating chamber. The distances between the holes vary along a long side direction of the linear opening portion of the heating chamber.

The deposition apparatus preferably further includes a conveying unit adapted to move the deposition source to emit a material, which is to be deposited, in a first direction.

The conveying unit is preferably adapted to move the deposition source in an up-and-down direction to emit the material in a horizontal direction.

According to yet another aspect of the present invention, a deposition apparatus having a deposition source is provided including: a heating chamber having a linear opening portion; and a cover including a plurality of holes and attached to the linear opening portion of the heating chamber. The number of holes arranged in a short side direction of the linear opening portion of the heating chamber varies along a long side direction of the linear opening portion of the heating chamber.

The deposition apparatus preferably further includes a conveying unit adapted to move the deposition source to emit a material, which is to be deposited, in a first direction.

The conveying unit is preferably adapted to move the deposition source in an up-and-down direction to emit the material in a horizontal direction.

### BRIEF DESCRIPTION OF THE DRAWINGS

A more complete appreciation of the present invention and many of the attendant advantages thereof, will be readily apparent as the present invention becomes better understood by reference to the following detailed description when considered in conjunction with the accompanying drawings in which like reference symbols indicate the same or similar components, wherein:

FIG. 1 is a schematic perspective view of a linear deposition source;

FIG. 2 is a graph illustrating a thickness of a thin film deposited using the deposition source of FIG. 1;

FIG. 3 is a schematic perspective view of a deposition source according to an embodiment of the present invention;

FIG. 4 is a cross-sectional view of the deposition source of FIG. 3 taken along line IV-IV;

FIG. 5 is a graph illustrating a thickness of a thin film deposited using the deposition source of FIG. 3;

FIG. 6 is a cross-sectional view of a modified example of the deposition source of FIG. 4;

FIG. 7 is a schematic perspective view of a deposition source according to another embodiment of the present invention; and

FIG. 8 is a conceptional view of a deposition apparatus according to an embodiment of the present invention.

### DETAILED DESCRIPTION OF THE INVENTION

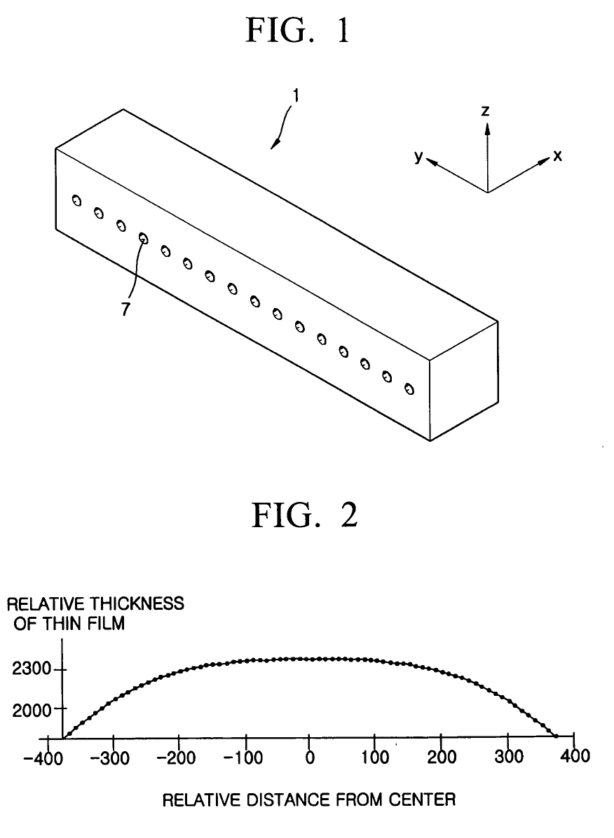

FIG. 1 is a schematic perspective view of a linear deposition source 1. Referring to FIG. 1, a plurality of holes 7 are formed on a front surface of the deposition source 1, and the material in the deposition source 1 is evaporated and discharged through the holes 7. The holes 7 formed on the deposition source 1 are spaced apart from each other at equivalent distances, and thus, the thickness of the thin film deposited by the deposition source 1 is not uniform as shown in FIG. 2. In particular, the thickness of the deposited thin film becomes thinner in a direction from the center of the thin film toward either edge of the thin film.

In order to solve the above problem, the substrate is rotated or a distance between the deposition source and the substrate is maximized. However, there is a limitation as to increasing the distance between the substrate and the deposition source due to the limitation of size. In addition, when the substrate is rotated, the density (thickness) of the thin film deposited on the substrate is not uniform according to an incident angle of the deposited material onto the substrate.

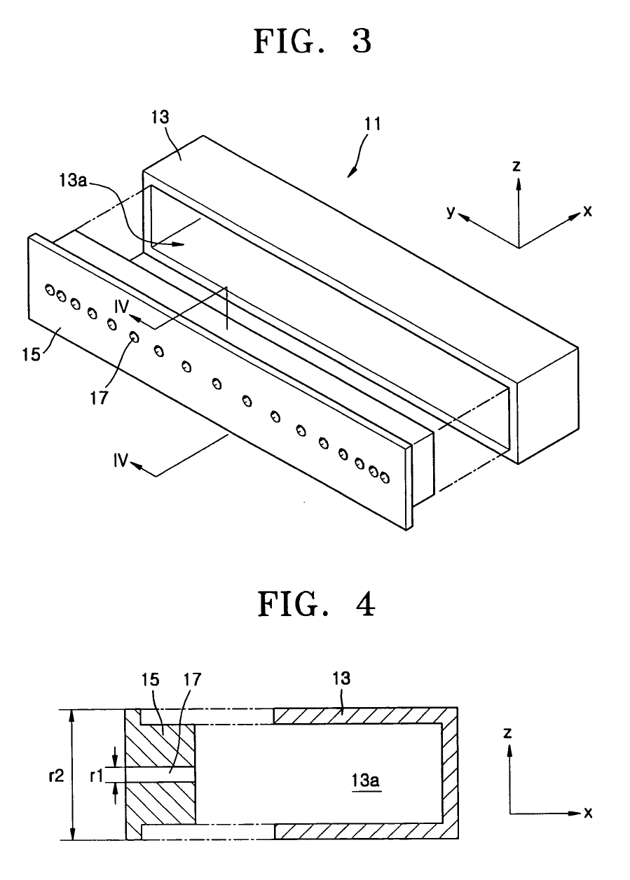

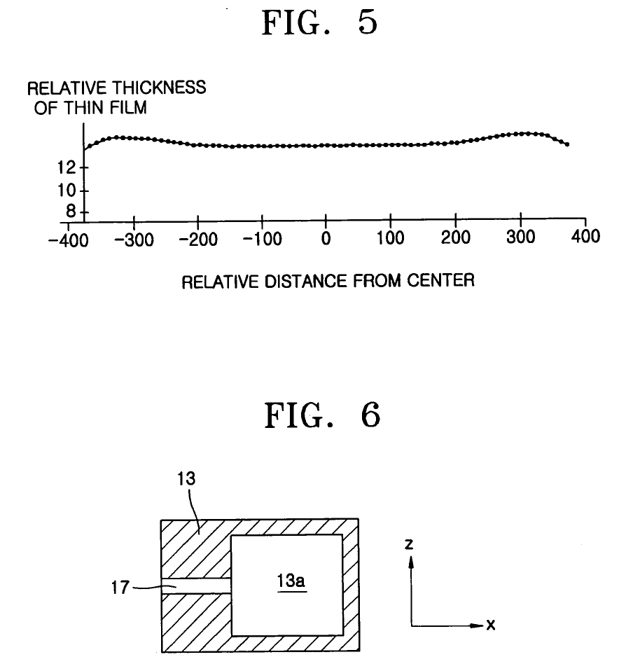

FIG. 3 is an exploded perspective view of a deposition source 11 according to an embodiment of the present invention, FIG. 4 is a cross-sectional view of the deposition source 11 of FIG. 3 taken along line IV-IV, and FIG. 5 is a graph illustrating a thickness of a thin film deposited using the deposition source 11 of FIG. 3.

Referring to FIGS. 3 through 5, the deposition source 11 includes a heating chamber 13 having a linear opening portion, and a cover 15 coupled to the linear opening portion of the heating chamber 13. A plurality of holes 17 are formed on the cover 15, and a deposition 11 material disposed inside 13a of the heating chamber 13 is discharged through the holes 17. The deposition source 11 can be modified variously, for example, heating coils (not shown) for heating the heating chamber 13 can be disposed on the deposition source 11.

The holes 17 formed on the cover 15 are arranged in a row in a long side direction of the linear opening portion of the heating chamber 13, that is, in the y direction of FIG. 3. In addition, distances between the holes 17 formed on the cover 15 are changed along the long side direction of the linear opening portion of the heating chamber 13, that is, in the y direction or −y direction. When the distances between the neighboring holes 17 are changed, the number of holes 17 disposed at edge portions of the cover is larger than the number of holes 17 disposed at a center portion of the cover, and thus, the thickness of the thin film deposited using the deposition source 11 becomes uniform.

When the holes are arranged with the same intervals therebetween, the thickness of the deposited thin film becomes thinner in a direction from the center of the thin film toward either edge of the thin film, as shown in FIG. 2. Therefore, the distance between the two neighboring holes 17 formed on the cover 15 is reduced in a direction toward either end of the cover from the center portion of the linear opening portion of the heating chamber 13, that is, along the y direction or −y direction from the center of the cover 15. Then, the thickness of deposited thin film becomes uniform.

The distances between the holes 17 formed on the cover 15 can be determined via a simulation. If it is assumed that a mass flow rate of the material to be deposited is m, a shape coefficient is n, a distance between the deposition source 11 and the substrate is S, a density of the material to be deposited is ρ, a radiation angle is Φ, and an incident angle of the material is θ, a thickness d of the thin film deposited at a certain point is as follows.

$$d = \frac{m ( n + 1 )}{2 π {S}^{2} ρ} {cos}^{n} Φ cos θ \qquad ( 1 )$$

The mass flow rate m denotes a flux of the material to be deposited that is discharged from the deposition source 11, and it is a constant determined by the temperature. The shape coefficient n denotes a schematic shape of the material discharged from a hole, and it is a constant determined by a shape of the hole 17 of the deposition source 11 or the material. In addition, the radiation angle Φ denotes a radiation angle of the material from the hole 17 of the deposition source 11. The injection shape of the material to be deposited can be represented as a bell from each hole 17, and the radiation angle Φ is an angle between a segment of a line connecting the each hole 17 to a certain point in the bell shape and a segment of a line extending from the hole 17 perpendicularly to the substrate. The incident angle θ is an incident angle of the material onto a certain point of the substrate.

As described above, the thickness of thin film that is to be deposited under a certain environment, for example, with the shape of the hole 17 on the deposition source 11 or a temperature of deposition, can be calculated through the simulation, and thus, the distances between the holes 17 for depositing a uniform thin film can be determined based on the calculation under certain conditions. Through the above processes, the positions of holes 17 formed on the deposition source 11 can be calculated in advance, and then, the deposition process is performed and the thin film having the constant thickness can be deposited. Consequently, the distances between the holes 17 formed on the cover are reduced in a direction towards both ends of the linear opening portion of the heating chamber 13 from the center of the linear opening, that is, reduced gradually along the y direction or −y direction from the center of the cover 15.

In order to form the thickness of a certain portion of the thin film to be thicker or thinner than those of other portions, the distances between the holes 17 formed on the cover 15 can be controlled in the long side direction on the linear opening portion of the heating chamber 13, that is, in the y direction or −y direction of FIG. 3.

Referring to FIGS. 3 and 4, the material to be deposited is placed inside 13a of the deposition source 11 and is heated to be evaporated or sublimated, and then, is discharged through the holes 17 formed on the cover 15 to be deposited onto a deposition-object material such as the substrate. Therefore, the deposition can be performed efficiently when the injection speed of the material through the holes 17 is fast. A pressure of the inside 13a of the deposition source 11 should increase in order to improve the injection speed of the material, and thus, the maximum diameter r1 of the holes 17 formed on the cover 15 may be smaller than the width r2 of the linear opening portion of the heating chamber 13. Then, the injection speed of the material to be deposited can be increased, and thus, the deposition can be performed efficiently.

FIG. 5 is a schematic graph illustrating the thickness of the thin film deposited using the deposition source 11 according to the current embodiment of the present invention. As shown in FIG. 5, the thin film having the uniform thickness is deposited.

In FIGS. 3 and 4, the cover 15 including the holes 17 and the heating chamber 13 are fabricated separately and attached to each other. However, the cover 15 and the heating chamber 13 can be fabricated integrally with each other as shown in FIG. 6. In the case of the deposition source of FIGS. 3 and 4, the cover is separated from the heating chamber 13, and the material to be deposited is placed in the heating chamber 13. In addition, in the case of the deposition source of FIG. 6, the deposition source can include an opening and a cover thereof to insert the material into the heating source.

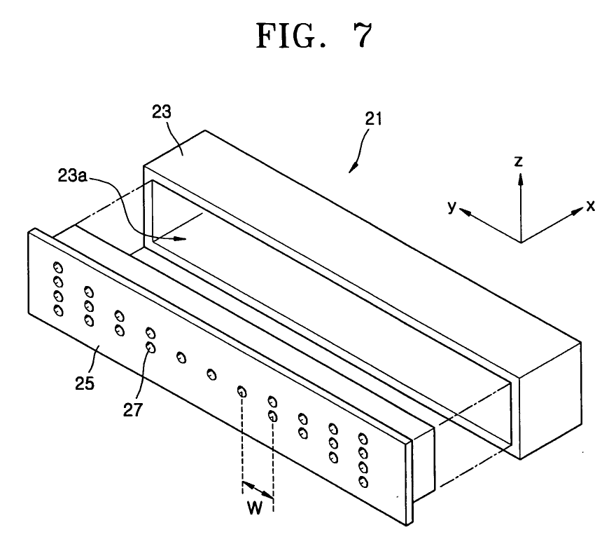

FIG. 7 is a perspective view of a deposition source according to another embodiment of the present invention.

Referring to FIG. 7, a deposition source 21 according to the current embodiment of the present invention includes a heating chamber 23 having a linear opening portion and a cover 25 attached to the linear opening portion of the heating chamber 23. The cover 25 includes a plurality of holes 27.

According to the deposition source of the current embodiment, the number of holes 27 arranged in a direction of short side of the linear opening portion is changed along a direction of long side of the linear opening portion. The long side direction of the linear opening portion of the heating chamber 23 is y direction or −y direction of FIG. 7, and the short side direction of the linear opening portion of the heating chamber 23 is z direction or −z direction of FIG. 7.

The number of holes 27 arranged in the short side direction of the linear opening portion of the heating chamber 23 is increased gradually along the long side direction of the linear opening portion, and thus, more holes are disposed on end portions corresponding to thin portions of the thin film deposited using the deposition source. Therefore, the thickness of the thin film deposited using the deposition source of the current embodiment becomes constant.

When the deposition source of FIG. 1 is used, the thickness of the deposited thin film becomes thinner in a direction from the center of the thin film toward either edge of the thin film, as shown in FIG. 2. Therefore, the number of the holes arranged in the short side direction of the linear opening portion is gradually increased along the long side direction of the linear opening portion of the heating chamber 23. Therefore, the thickness of the thin film becomes uniform.

In this case, a distance W between neighboring holes 27 in the long side direction of the linear opening portion of the heating chamber 23 can be constant. However, as in the previous embodiment, the distance W between the neighboring holes in the long side direction of the linear opening portion can be reduced along the long side direction of the linear opening portion of the heating chamber 23. In addition, the deposition source according to the current embodiment can be modified variously, for example, the cover 25 and the heating chamber 23 can be integrally formed with each other as described in the modified example of the previous embodiment.

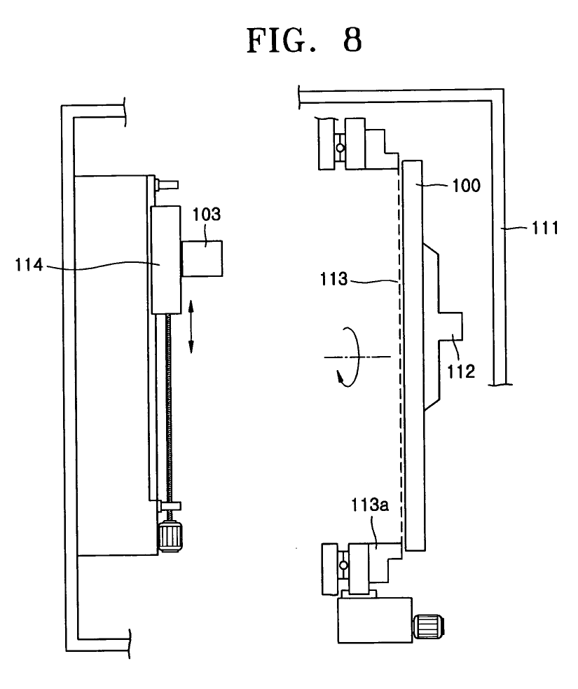

FIG. 8 is a conceptional view of a deposition apparatus including the deposition source.

Referring to FIG. 8, the deposition apparatus includes a chamber 111 therein, and the chamber 111 includes a substrate supporter 112 supporting a substrate 100, on which a deposition will be performed, a deposition mask 113 attached to the substrate 100 and including slits of a pattern that is to be deposited, a supporting unit 113a supporting the deposition mask 113, and a deposition source 103 facing the substrate 110 while interposing the deposition mask 113 therebetween. In addition, the deposition apparatus can further include a unit for attaching the deposition mask 113 to the substrate 100.

The substrate supporter 112 supports edges of the substrate 100 so that a deposition surface of the substrate 100 can correspond to the deposition source 103. However, the substrate supporter. 112 is not limited thereto. In addition, in the deposition apparatus, the substrate 100 is disposed in a vertical direction in order to prevent the substrate 100 from drooping due to the weight thereof. Accordingly, the deposition source 103 emits the material to be deposited onto the substrate 100 in a horizontal direction, and the deposition apparatus can further include a conveying unit 114 for moving the deposition source 103 in up-and-down direction so that the deposition source 103 can perform the deposition process while moving in the up-and-down direction.

In addition, a plurality of deposition sources can be formed in the deposition apparatus unlike the apparatus of FIG. 8, and the deposition apparatus is not limited to the example of FIG. 8.

In the deposition apparatus, the deposition sources according to the previous embodiments of the present invention can be used as the deposition source 103, and then, an organic layer or a metallic layer can be deposited onto the substrate 100 to a constant thickness. Therefore, an organic ElectroLuminescence (EL) display apparatus that can reproduce images of uniform image quality on the entire screen can be fabricated.

According to the deposition source and the deposition apparatus including the deposition source of the present invention, the thickness of deposited thin film can be controlled by changing distances between the neighboring holes, which are formed on the linear opening portion of the heating chamber in the deposition source, in the long side direction of the linear opening portion. In addition, when the distances between the holes formed on the linear opening portion of the heating chamber are reduced toward either end portion of the linear opening portion from the center of the linear opening portion in the long side direction, a thin film having the constant thickness is deposited.

In addition, the thickness of deposited thin film can be controlled by changing the number of holes arranged in the short side direction of the linear opening portion along the long side direction of the linear opening portion. That is, the number of holes arranged in the short side direction of the linear opening portion of the heating chamber is increased along the long side direction of the linear opening portion, and a thin film having the constant thickness is deposited.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A deposition source, comprising:
a heating chamber having a linear opening portion; and
a cover including a plurality of holes and attached to the linear opening portion of the heating chamber;
wherein distances between the holes vary along a long side direction of the linear opening portion of the heating chamber.

2. The deposition source of claim 1, wherein the distances between the holes are reduced in a direction towards either end portion from a center of the linear opening portion in the long side direction of the linear opening portion of the heating chamber.

3. The deposition source of claim 1, wherein the holes on the cover are arranged in a row in the long side direction of the linear opening portion of the heating chamber.

4. The deposition source of claim 1, wherein a maximum diameter of the holes on the cover is less than a width of the linear opening portion of the heating chamber.

5. The deposition source of claim 1, wherein the cover is integral with the heating chamber.

6. A deposition source, comprising:
a heating chamber having a linear opening portion; and
a cover including a plurality of holes and attached to the linear opening portion of the heating chamber;
wherein the number of holes arranged in a short side direction of the linear opening portion of the heating chamber varies along a long side direction of the linear opening portion of the heating chamber.

7. The deposition source of claim 6, wherein the number of holes arranged in the short side direction of the linear opening portion of the heating chamber increases in a direction towards either end portion from a center of the linear opening portion in the long side direction of the linear opening portion of the heating chamber.

8. The deposition source of claim 6, wherein distances between the plurality of holes are constant in the long side direction of the linear opening portion of the heating chamber.

9. The deposition source of claim 6, wherein distances between the plurality of holes on the cover are reduced in a direction towards either end portion from a center of the linear opening portion in the long side direction of the linear opening portion of the heating chamber.

10. The deposition source of claim 6, wherein a maximum diameter of the plurality of holes is less than a width of the linear opening portion of the heating chamber.

11. The deposition source of claim 6, wherein the cover is integral with the heating chamber.

12. A deposition apparatus comprising a deposition source, including:
a heating chamber having a linear opening portion; and
a cover including a plurality of holes and attached to the linear opening portion of the heating chamber;
wherein distances between the holes vary along a long side direction of the linear opening portion of the heating chamber.

13. The deposition apparatus of claim 12, further comprising a conveying unit adapted to move the deposition source to emit a material, which is to be deposited, in a first direction.

14. The deposition apparatus of claim 13, wherein the conveying unit is adapted to move the deposition source in an up-and-down direction to emit the material in a horizontal direction.

15. A deposition apparatus comprising a deposition source, comprising:
a heating chamber having a linear opening portion; and
a cover including a plurality of holes and attached to the linear opening portion of the heating chamber;
wherein the number of holes arranged in a short side direction of the linear opening portion of the heating chamber varies along a long side direction of the linear opening portion of the heating chamber.

16. The deposition apparatus of claim 15, further comprising a conveying unit adapted to move the deposition source to emit a material, which is to be deposited, in a first direction.

17. The deposition apparatus of claim 16, wherein the conveying unit is adapted to move the deposition source in an up-and-down direction to emit the material in a horizontal direction.
